(19) United States
(12) Patent Application Publication
(10) Pub. No.: US 2009/0303452 A1
(43) Pub. Date: Dec. 10, 2009

(54) Image Enhancement Technique

(75) Inventor: Ulric Ljungblad, Molndal (SE)

Correspondence Address: HAYNES BEFFEL & WOLFELD LLP, P O BOX 366, HALF MOON BAY, CA, 94019, US

(73) Assignee: Micronic Laser Systems AB, Taby (SE)

(21) Appl. No.: 11/918,577

(22) PCT Filed: Apr. 15, 2005
(86) PCT No.: PCT/SE2005/000543

§ 371 Date: May 4, 2009

(51) Int. Cl. G03F 7/20; G03B 27/50

(52) U.S. Cl. 355/50

(57) ABSTRACT

The present invention relates to a method to improve at least one feature edge steepness in an image to be exposed onto a moving workpiece, comprising the actions of: moving the image in essentially the same direction relative to the direction of movement of the workpiece, synchronizing said moving of the image with a pulse length of an exposure radiation source. The invention also relates to a pattern generator for creating patterns on a workpiece

### TECHNICAL FIELD

Example embodiments of the present invention relate to a pattern generator and a method for the same.

### BACKGROUND OF THE INVENTION

Modern UV-lithography is inter alia searching for new highly parallel writing concepts. Spatial light modulation (SLM) with optical MEMS devices may offer such possibility. An SLM chip may comprise a DRAM-like CMOS circuitry with several million individually addressable pixels on top. Said pixels may be deflected due to a difference in electrostatic force between a mirror element and an address electrode. An example embodiment of a pattern generator using an SLM is described in U.S. Pat. No. 6,373,619 assigned to the same assignee as this invention. This patent discloses in short a small field stepper, which exposes a series of images of the SLM. A workpiece may be arranged on a stage, which may be continuously moving and a pulsed electromagnetic radiation source (which could be a pulsed laser, a flash lamp, a flash from a synchrotron light source, etc) may flash and freeze an image of the SLM on the workpiece. The SLM may be reprogrammed with a new pattern before each flash so a contiguous image may be composed on the workpiece.

One way of increasing the speed of patterning a substrate may be to increase the flash frequency and increasing the speed of the stage upon which the workpiece may be attached. An increased speed of the stage in combination with a fixed pulse length, may smear out the image on the workpiece. This can be overcome by using a shorter pulse length, however this may not always be possible or even desirable which may be a problem.

Therefore, what is needed in the art is a method to correct for said smeared out image when the stage is moving too far during a fixed pulse length.

### SUMMARY OF THE INVENTION

Accordingly, it is an object of the present invention to provide a method, which eliminates or at least reduces the above-mentioned problem.

This object, among others, may according to a first aspect of the invention be attained by a method to improve at least one feature edge steepness in a stamp exposed onto a moving workpiece, comprising the actions of moving a pattern representing said stamp in essentially the same direction relative to a direction of movement of the workpiece, synchronizing said moving of the pattern with a pulse length of an exposure radiation source.

The invention also relates to a pattern generator in which a stamp may be exposed onto a workpiece, which may at least partly be covered with a radiation sensitive layer, comprising: a stage, continuously moving in a first direction, upon which said workpiece may be attached, at least one mechanical component capable to move a pattern representing said stamp on said workpiece in said first direction, a synchronizer which may synchronize a pulse length with said movement of the pattern in said first direction.

Further characteristics of the invention, and advantages thereof, will be evident from the detailed description of preferred embodiments of the present invention given hereinafter and the accompanying FIGS. 1-6, which are given by way of illustration only, and thus are not limitative of the present invention.

### BRIEF DESCRIPTION OF THE DRAWINGS

FIG. 1 depicts a schematic overview of a prior art pattern generator using a spatial light modulator which may include the present inventive method.

FIG. 2 depicts a stage and an oscillating image movement as a function of time.

### DETAILED DESCRIPTION

The following detailed description is made with reference to the figures. Preferred embodiments are described to illustrate the present invention, not to limit its scope, which is defined by the claims. Those of ordinary skill in the art will recognize a variety of equivalent variations on the description that follows.

Further, the preferred embodiments are described with reference to an analogue SLM. It will be obvious to one with ordinary skill in the art that there may be situations when other SLMs than analogue ones will be equally applicable; for example digital SLMs like a digital micromirror device (DMD) made by Texas instruments. Additionally, SLM:s may be comprised of reflective or transmissive pixels. Even further, the preferred embodiments are described with reference to an excimer lacer source. It will be obvious to one with ordinary skill in the art that a pulsed electromagnetic radiation source other than an excimer laser may be used, for instance an Nd-YAG laser, ion laser, Ti sapphire laser, free electron laser or other pulsed fundamental frequency lasers, flash lamps, laser plasma sources, synchrotron light sources etc.

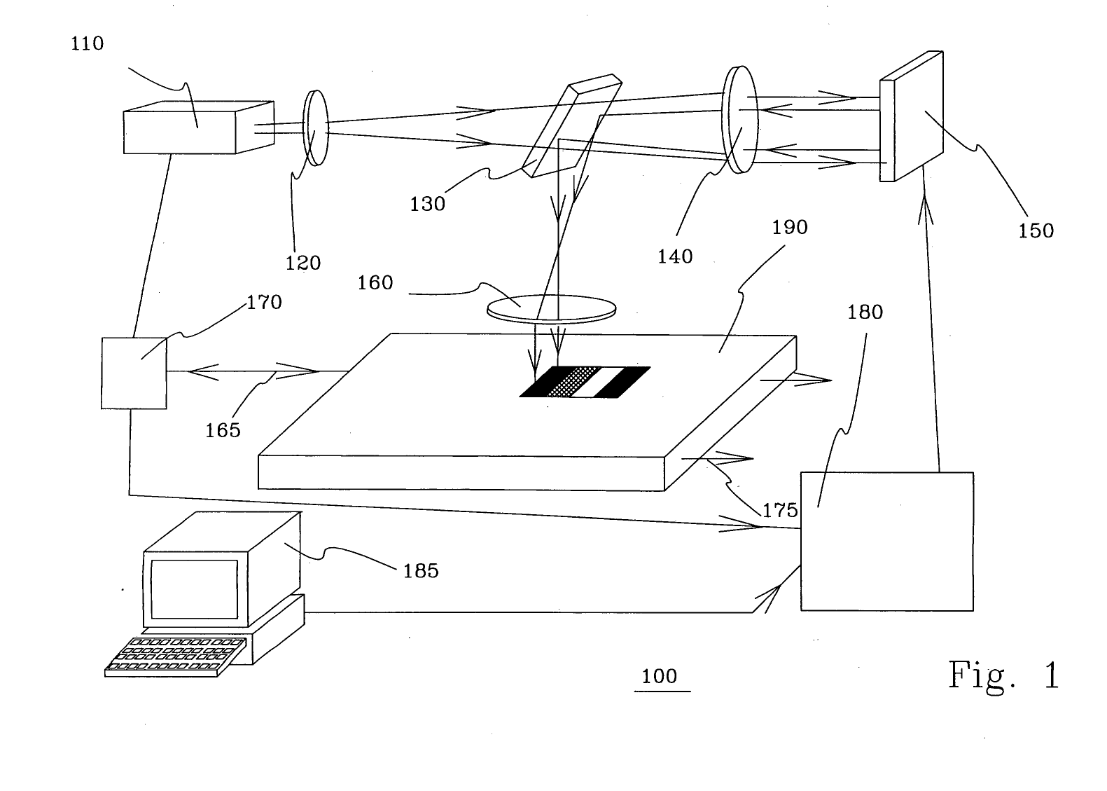

FIG. 1 illustrates schematically a pattern generator using a spatial light modulator according to prior art technology. Said pattern generator may benefit by the present invention. Said pattern generator comprises an electromagnetic radiation source 110, a first lens 120, a semitransparent mirror 130, a second lens 140, a spatial light modulator 150, a third lens 160, an interferometer 170, a pattern bitmap generator 180, a computer 185, a workpiece 190.

The laser source 110 may be an excimer laser emitting for instance 308 nm, 248 nm, 193 nm, 156 nm, or 126 nm pulses. Said pulses are homogenized and shaped by the homogenizing and shaping lenses 120, 140. Said lenses 120, 140 comprise optics such that plane waves are exposing the surface of the SLM 150. The temporal pulse length of the laser may be 0.1 μs or smaller, for instance 10 ns. The pulse repetition rate of the laser may be 0.5-5 kHz, for instance 2 kHz.

The third lens 160 determines the demagnification of the system. When using an analogue spatial light modulator, a spatial filter and a Fourier lens (not illustrated in the figure) are arranged between the third lens 160 and the semitransparent mirror 130.

The computer 185 may generate the pattern to be imaged onto the workpiece. Said workpiece may be a transparent substrate covered with a layer with chrome which in turn may be covered with a layer of photosensitive material. This may be an example of a workpiece used in the manufacturing of masks and reticles. The workpiece may also be a semi-conducting wafer onto which the pattern is directly generated without a mask. This pattern may be generated by conventional software used in the lithography industry. Said pattern may be transformed into a bitmap representation by the pattern bitmap generator 180. Said bitmap representation may in its turn be transformed into drive signals for the spatial light modulator by said bitmap generator 180. Said drive signals may set individual pixel elements in said spatial light modulator 150 into a desired modulation state. Li case of an analogue spatial light modulator a specific drive signal will correspond to a specific deflection state of a particular pixel element. Deflection states of an analogue pixel element such as a micro mirror operated in an analogue mode may be set to any number of states between fully deflected and non-deflected, for instance 64, 128 or 256 states.

The interferometer 170 continuously detects the position of the workpiece. The workpiece may move with a constant speed when patterning a strip of stamps. The workpiece may also move with a variable speed. When the workpiece moves with a variable speed, it may be necessary to detect the actual speed a short time period before illuminating the SLM in order to be sure that a stamp of the SLM will be printed at a requested position on the workpiece. The stamp may be a reproduction of the pattern of the SLM onto the workpiece. A reduction of the pattern of the SLM may be performed through one or a plurality of lenses before being reproduced onto the workpiece. Several stamps stitched together may form a strip. Strips stitched together may form a complete image. The interferometer 170 may transmit and receive signals 165 for detecting said position of the workpiece. When the workpiece, at a given position, may be detected by said interferometer, a trigger signal may be sent to the laser. One way of generating said trigger signal may be to compare a detected value of position of the workpiece with a stored value of position. When there is a match between a stored value of position, in for example a look up table, and a detected value of position a trigger signal may be generated. Said trigger signal may eventually cause the laser to pulse.

At a pulse rate of 1 kHz and a demagnified SLM size in the direction of movement of the workpiece of 50 μm, the writing speed will be 50 mm/s. At 1 kHz pulse rate and with a temporal pulse length of each pulse of 10 ns, there is a time space of 0.99 μs between each pulse.

In one example embodiment according to the present invention the SLM 150 may be arranged on a movable support. A movement of said support may be synchronized with a pulse length of an exposure source. The movement of the support during said pulse length is made to at least partly counteract the movement of the stage. In one example embodiment according to the present invention the support may be moved by piezo electrical actuators. In another example embodiment of the present invention, the support may be moved by a step motor. In still another example embodiment according to the present invention the support may be brought into an oscillating motion.

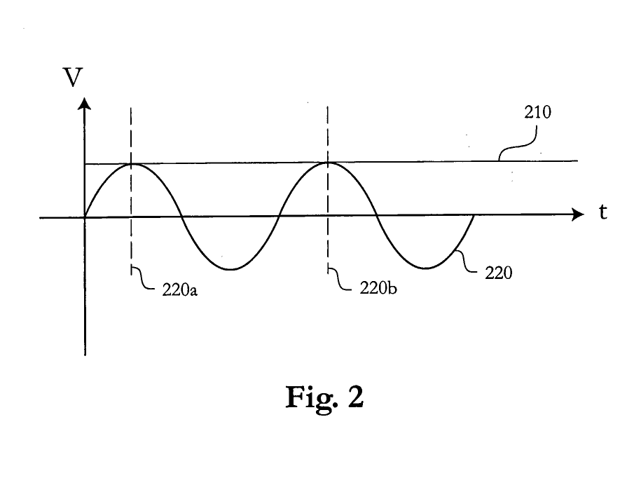

FIG. 2 illustrates the velocity of the stage denoted 210 and the velocity of a mechanical component, denoted 220, capable to move the pattern to be exposed onto the workpiece as a function of time. Here, the mechanical component may be oscillating back and forth. Since the stage in this example embodiment is moving with a constant velocity, a flash from the exposure radiation source may be synchronized with the oscillating motion in order to counteract the effect of smearing out the stamp while the laser is flashing and the stage is moving. The laser may be synchronized to flash when a direction of movement of the support is the same as the direction of movement of the stage. In this example embodiment, the maximum amplitude of the oscillating movement is to its absolute value equal to the constant speed of the stage. In order to counteract the smearing out effect, the synchronization of the laser flash may be performed at the maximum points 220a, 220b of the oscillating curve 220. It is obvious to a person skilled in the art that any amplitude of the oscillating movement may be used. If using too low amplitude, further compensation may be performed by other methods. If using too high amplitude of the oscillating movement, one may synchronize the flashing of the exposure radiation at other point than the maximum points with equal or less effect as the example embodiment depicted in FIG. 2.

hi another example embodiment according to the present invention said pattern may move in the same direction in relation to the stage by moving the semitransparent mirror. Said mirror could be moved by means of piezo electrical actuation, by means of a stepping motor or by means of bringing said semi transparent mirror into an oscillating action. The semitransparent mirror may be arranged on a support structure. Said support structure together with the semitransparent mirror has a specific self resonance. By applying a certain frequency with a certain amplitude on said support structure and semitransparent mirror, said mirror could be oscillating at its resonance frequency. The synchronization may be performed in a similar manner as described in connection with the moving SLM.

In yet another example embodiment according to the present invention, one or a plurality of lenses 140, 160 may be moved in order to move the pattern to be exposed onto the workpiece. Said lenses may be moved by piezo electrical actuation, by stepping motor or by self resonance in a similar manner as described in connection with the other embodiment above.

hi still another example embodiment according to the present invention, the stamp may be freezed at certain points by applying an oscillating movement on top of the continuous movement of the stage. Said oscillation may be synchronized with the pulse length of the laser. The oscillation of the stage may freeze the stage movement at certain time intervals if the amplitude is correctly chosen in relation to the continuous speed of the stage.

hi yet another example embodiment according to the present invention, said pattern may be moved by electrooptical deflection or acoustooptical deflection. An electrooptical deflector or an acoustooptical deflector may be placed in between the spatial light modulator and the workpiece. The pattern may be moved in the same direction as the direction of movement of the stage.

While the present invention is disclosed by reference to the preferred embodiments and examples detailed above, it is understood that these examples are intended in an illustrative rather than in a limiting sense. It is contemplated that modifications and combinations will readily occur to those skilled in the art, which modifications and combinations will be within the spirit of the invention and the scope of the following claims.

1. A method to improve at least one feature edge Steepness in a stamp exposed onto a moving workpiece, comprising the actions of:
Moving a pattern representing said stamp in essentially the same direction relative to the direction of movement of the workpiece,
synchronizing said moving of the pattern with a pulse length of an exposure radiation source.

2. A method according to claim 1, wherein said exposure radiation source is a pulsed radiation source.

3. The method according to claim 1, further comprising the action of:
providing an oscillating movement of a mechanical component to achieve said moving of the pattern.

4. The method according to claim 1, wherein said mechanical component is at least one of the group of: SLM (Spatial Light Modulator); beam splitter; lens; stage; mirror.

5. A pattern generator in which a stamp is exposed onto a workpiece, which is at least partly covered with a radiation sensitive layer, comprising:
a stage, continuously moving in a first direction, upon which said workpiece is attached,
at least one mechanical component capable to move a pattern representing said stamp on said workpiece in said first direction,
a synchronizer which synchronizes a pulse length with said movement of the pattern in said second direction.

6. The pattern generator according to claim 5, wherein said pattern generator is one of the group of DW (Direct Writer), mask writer, stepper, scanner.

7. The pattern generator according to claim 5, wherein an exposure radiation source is a pulsed radiation source.

8. The pattern generator according to claim 5, wherein said at least one mechanical component is at least one of the group of: SLM (Spatial Light Modulator); beam splitter; lens; state; mirror.

9. The pattern generator according to claim 5, wherein said mechanical component is capable to oscillate to achieve said moving of the pattern.

10. The pattern generator according to claim 5, further comprising an electrooptical or acoustooptical deflector capable to deflect the pattern in said first direction.

11. The method according to claim 1, further including the action of:
deflecting the pattern representing said stamp in essentially the same direction relative to the direction of movement of the workpiece,
synchronizing said deflecting of the pattern with a pulse length of an exposure radiation source.

12. The method according to claim 4, further including the action of:
deflecting the pattern representing said stamp in essentially the same direction relative to the direction of movement of the workpiece,
synchronizing said deflecting of the pattern with a pulse length of an exposure radiation source.
